(19) United States
(12) Patent Application Publication
(10) Pub. No.: US 2009/0233181 A1
(43) Pub. Date: Sep. 17, 2009

(54) POROUS HOLOGRAPHIC FILM

(75) Inventors: Christianus Martinus Van Heesch, Eindhoven (NL); Carlos Sanchez, Zaragosa (ES); Michael James Escuti, Cary, NC (US); Cornelis Wilhelmus Maria Bastiaansen, Eindhoven (NL); Dirk Jan Broer, Eindhoven (NL)

Correspondence Address: THORNE & HALAJIAN;APPLIED TECHNOLOGY CENTER, 111 WEST MAIN STREET, BAY SHORE, NY, 11706, US

(73) Assignee: DUTCH POLYMER INSTITUTE, EINDHOVEN (NL)

(21) Appl. No.: 11/721,059

(22) PCT Filed: Dec. 9, 2005
(86) PCT No.: PCT/IB05/54150

§ 371 Date: Jun. 7, 2007

(30) Foreign Application Priority Data
Dec. 14, 2004 (EP) 04106543.4

(51) Int. Cl. G03F 7/00

(52) U.S. Cl. 430/2

(57) ABSTRACT

The present invention relates to a method for the manufacture of a holographic film. The method includes a polymerizable composition that comprises monomers with high reactivity, monomers with low reactivity and a non-reactive material. The method comprises a patterned exposure to obtain a patterned polymerization of the monomers with high reactivity and a subsequent polymerization to polymerize also monomers with low reactivity to form a solid film. The method gives a holographic film with a high refractive index modulation and a modulated porosity.

### TECHNICAL FIELD

The present invention relates to a method for the manufacture of a holographic film, in which film the refractive index is modulated between a first and a second refractive index, said first refractive index being higher than said second refractive index.

The present invention also relates to such a holographic film and a photo-polymerizable composition for use in the manufacture of such a holographic film.

### TECHNICAL BACKGROUND

Holographic thin films are increasingly used in Liquid Crystal Displays (LCDs) for “light-management” purposes (non-absorptive generation of polarized light/color, controlling the directionality of light), and in optical processing in general.

For example, holographic layers have been proposed as an alternative for outcoupling systems. U.S. Pat. No. 6,750,669 of Jagt et al discloses the use of a slanted transmission volume hologram on top of the wave-guide in transparent isotropic materials in such a way that unidirectional, polarized, and color-separated emission is generated, where the grating may be recorded with UV-laser radiation in a way that allows recording in a standard transmission hologram setup.

The operation of this device depends critically on the product (n_{high}−n_{low})(d/λ), where n_{high} and n_{low} are the high and low refractive index values of the holographic material, d is the hologram layer thickness, and λ is the wavelength of operation. When this product is large enough, the transmission hologram can be “over-modulated” such that diffraction for one linear polarization is high while diffraction for the orthogonal polarization is close to zero.

One limitation of the prior art device is the difficulty of finding a high quality UV-sensitive holographic material with an index contrast that is high enough to permit thin layers to be used. Often, highly efficient holograms with a high refractive index modulation (Δn>0.02) are required to generate the desired optical characteristics.

Further, in some cases it would be advantageous to provide porous holographic materials. The pores may be filled with functional compounds to provide additional functionality to the material.

U.S. Pat. No. 4,588,664, to H. Fielding, discloses a porous holographic material called DMP-128 with high index modulation. The processing of this material, to obtain the desired properties, is however complicated and comprises a plurality of steps under different conditions, and the functionalization of the resulting hologram is not straightforward.

Thus, there still remains need for new holographic materials with a high refractive index modulation and porous structure.

### SUMMARY OF THE INVENTION

One object of the present invention is thus to overcome at least some of the drawbacks of the prior art. This is accomplished by providing a new method, which allows for the manufacture of a holographic film having a high refractive index modulation and a porous structure, as well as by providing such a holographic film.

The method gives a holographic film with a high refractive index modulation and a modulated porosity.

Thus, in a first aspect, the present invention provides a method for the manufacture of a holographic film. The method comprises providing a substrate; arranging a (photo-)polymerizable composition on the substrate, the (photo-)polymerizable composition comprising: (i) monomers with high reactivity, (ii) monomers with low reactivity, (iii) non-reactive material and (iv) a photo-inducible or photo-sensitive polymerization initiator, or photo-initiator.

The reactivity of the high-reactive monomers is high relative to the reactivity of the monomers with low reactivity such that exposure of the photo-polymerizable composition causes selective polymerization of the monomers with high reactivity in the parts of the composition exposed to light and diffusion of monomers of low reactivity and non-reactive monomers away from and monomers of high reactivity towards the exposed parts.

First, polymerization is preferentially induced in at least part of said monomers with high reactivity in at least one region of said composition, and secondly polymerization is induced in at least part of said monomers with low reactivity preferentially in the other regions of the hologram.

For instance, a spatially modulated light intensity pattern, such as for example a interference pattern, is used to first polymerize the highly reactive monomer in the high light intensity regions. The monomer with a low reactivity (and any residual monomers of high reactivity) is then polymerized, for example with a flood exposure or by heat treatment.

Subsequently the non-reactive material, such as a volatile solvent, may be evaporated or otherwise removed to generate a porous and low refractive index material in the regions with a low light intensity during the first illumination procedure with a spatially modulated light pattern.

Such formed pores may for example be filled with functional compounds, for example liquid crystals, fluorescent dyes, absorbing dyes, electro-luminescent compounds, conducting materials, semi-conducting materials to provide additional functionality to the holographic film of the present invention.

The monomers with high reactivity in the polymerizable composition may for example be mono- and/or polyfunctional acrylates, methacrylates and any mixture thereof.

The monomers with low reactivity in the polymerizable composition may for example be mono- and/or polyfunctional epoxy compounds and any mixture thereof.

In a second aspect, the present invention relates to a holographic film comprising a polymeric film wherein the refractive index of said polymeric film is periodically modulated between a first and a second refractive index. The polymer film exhibits a porosity periodically modulated between a first and a second porosity causing the modulation of between the first and the second refractive index. Further, the polymer film comprises at least a first and a second polymerized monomer, wherein the concentration of the first polymerized monomer is periodically modulated, coincident with the modulation of the refractive index, between a first and a second concentration.

In additional aspects, the present invention also relates to a photo-polymerizable composition comprising a monomer with high reactivity, a monomer with low reactivity, a photo-inducible polymerization initiator and a non-reactive material, the use of such a photo-polymerizable composition as well as a photo-polymerizable element comprising such a photo-polymerizable composition arranged on a substrate.

### BRIEF DESCRIPTION OF THE DRAWINGS

The present invention will now be further describes in the following description of preferred embodiments with reference to the accompanying drawings, wherein:

FIG. 1, a-d, outlines a method for the manufacture of a holographic film of the present invention.

FIG. 2 shows the angular intensity of outcoupled light (red (-), green (-^{•}-) and blue(^{•••})) from a slanted grating prepared as in example 1.

FIG. 3 is an electron microscope photo of a slanted grating prepared with a method according to the present invention. The slant angle φG is indicated in the figure.

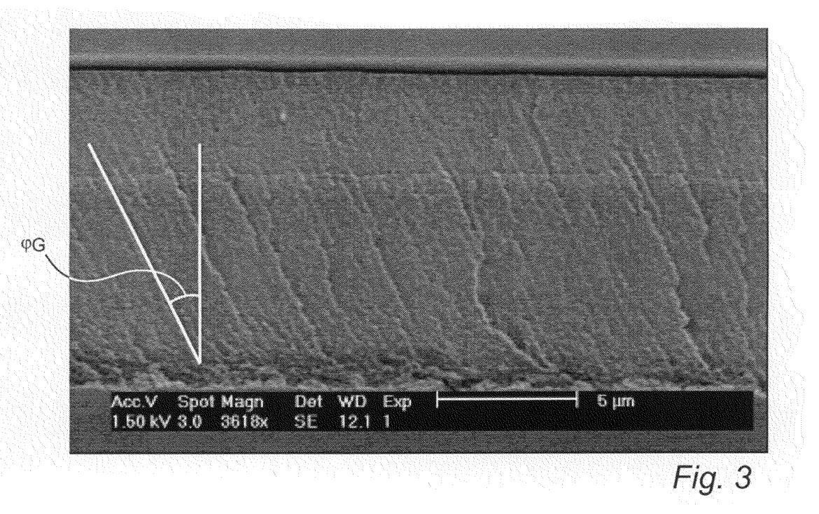

### DETAILED DESCRIPTION OF PREFERRED EMBODIMENTS

The present invention relates to a method for the manufacture of a holographic film. The method includes providing a polymerizable composition that comprises monomers with high reactivity, monomers with low reactivity and a non-reactive material. The method comprises a patterned exposure to obtain a patterned polymerization of the monomers with high reactivity and a subsequent polymerization to polymerize also monomers with low reactivity to form a solid film.

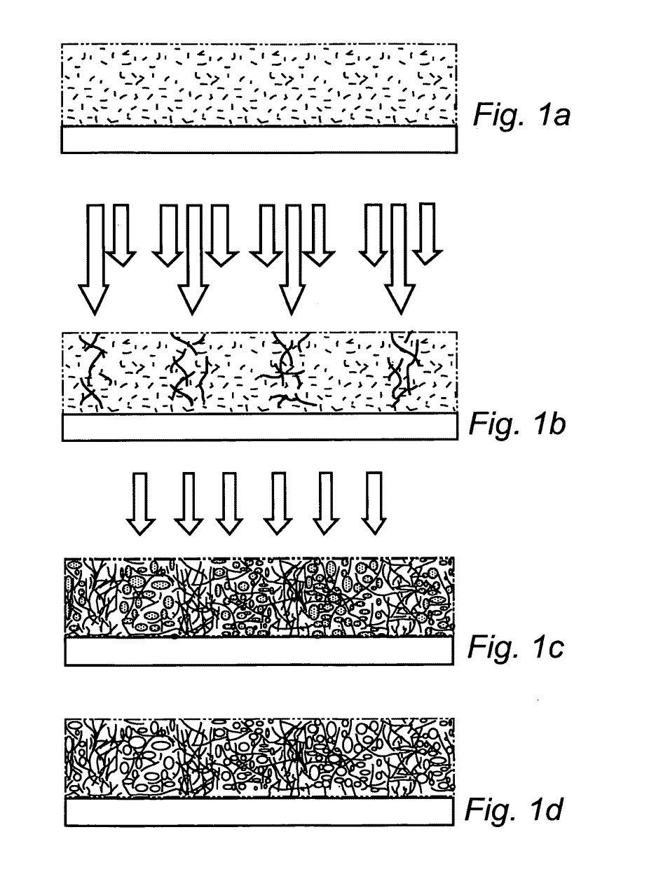

A method for the manufacture of a holographic film is outlined in FIG. 1 and may be performed as follows.

On a substrate, a liquid photo-polymerizable composition is arranged as a film (FIG. 1a). The photo-polymerizable composition comprises monomers with high reactivity, monomers with low reactivity, non-reactive material and a photo-sensitive polymerization initiator or a photo-initiator.

The composition may also comprise additional components, such as for example thermo-sensitive polymerization initiators, surfactants and polymerization inhibitors.

The term “reactive monomers” or similar expressions as used herein, relates to any compound that polymerizes spontaneously or in combination with a suitable polymerization initiator or in combination with suitable radiation or at certain temperatures. Thus, the term “reactive monomer” also relates to reactive pre-polymers and reactive oligomers.

The term “monomer with high reactivity” relates to a monomer having a higher reactivity, i.e. a lower activation energy as compared to a “monomer with low reactivity” and vice versa.

To induce polymerization of monomers with high reactivity and to induce the patterning of the refractive index in the film, a first, pattern inducing exposure is performed, wherein the photo-polymerizable composition is exposed to a periodically modulated light-pattern of dark and bright regions, for example light from a interference pattern generated with holography. Alternatively, the composition may be exposed through a mask.

In the regions of the photo-polymerizable composition exposed to the bright regions of the light-pattern, a polymerization is initiated, especially in the monomers with high reactivity. The initiated polymerization induces a polymerization driven diffusion of monomers with high reactivity towards the exposed regions, forming a dense polymer of such monomers with high reactivity in the exposed regions of the composition (FIG. 1b).

The polymerization-induced diffusion of monomers with high reactivity towards the exposed regions is met by a counter diffusion of monomers with low reactivity and non-reactive material towards the non-exposed regions of the composition.

To induce polymerization of also the monomers with low reactivity, and residual monomers with high reactivity, a second polymerization step is performed. This may be for example be obtained by exposing the composition to a polymerization inducing light, e.g. by a flood exposure of essentially the total composition, or by heating the composition to an appropriate temperature for thermal polymerization.

This results in a solid polymerized composition with a concentration modulation, where the regions exposed to a high light intensity of the composition comprises a polymer with a higher concentration of the monomers with high reactivity, and the regions exposed to a low light intensity comprises a polymer with a higher concentration of the monomers with low reactivity (FIG. 1c).

Due to the polymerization driven diffusion of monomers with high reactivity and the counter diffusion of monomers with low reactivity and non-reactive material in the previous step (FIG. 1B), the regions initially not exposed to the bright regions comprise a higher concentration of non-reactive material, leading to the formation of a less dense polymer network in these regions.

The non-reactive material, which now is predominantly located in the regions not initially exposed, i.e. in the regions with predominantly polymerized monomers with low reactivity, may then be removed from the solid composition, which leaves empty pores in the solid composition (FIG. 1d).

The non-reactive material may be removed in different ways depending on the nature of it, e.g. evaporation for a volatile non-reactive material or extraction, e.g. super critical extraction, for a material with a low volatility.

Preferably, the composition is formulated such that the size of the pores in the polymerized composition, after the removal of the non-reactive material, is in the nanometer range, such as from 1 to 100 nm, for example 1 to 10 nm. A pore size in this range gives very little incoherent scattering and a good transparency.

The pores are essentially stable, i.e. they do not collapse, which is probably related to the polymer network in the film.

The regions in the composition that was initially exposed to the bright regions of the light-pattern thus comprise a denser polymer with lower porosity as compared to the regions in the composition that was not initially exposed to the bright regions. This yields a solid film exhibiting a patterned refractive index, where the denser regions of the film exhibits a higher refractive index and the more porous regions of the film exhibits a lower refractive index. The refractive index pattern thus essentially coincides with the light-pattern used in the initial exposure, with higher refractive index corresponding to bright regions and lower refractive index corresponding to dark regions. Further, also the porosity of the solid composition essentially coincides with the light-pattern used in the initial exposure, with higher porosity corresponding to dark regions and lower porosity corresponding to bright regions.

With a method according to the present invention, a holographic film with a refractive index modulation Δn, i.e. the difference between the first, high, and the second, low, refractive index, higher than 0.02, for example higher than 0.04 has so far been obtained (see the experimental results below), and it is anticipated that even higher Δn values will be obtained under optimal conditions.

The difference in porosity between the high porosity and the low porosity may be at least 1%, such as at least 2%, for example at least 3% to at least 10% or higher.

Suitable materials for the substrate include glass and transparent ceramics. Preferably, the substrate is made of a transparent polymer which may be a thermosetting or thermoplastic, (semi)-crystalline or amorphous polymer. Examples include PMMA (polymethyl methacrylate), PS (polystyrene), PC (polycarbonate), COC (cyclic olefin copolymers), PET (Polyethylene terephthalate), PES (polyether sulphone), but also cross-linked acrylates, epoxies, urethane and silicone rubbers.

In some embodiments of the present invention, the surface of the substrate may be modified to form bonds, e.g. covalent, ionic, van der Waals and/or hydrogen bonds to the film, in order to further improve the physical integrity and strength of the polymerized film. Such modifications include e.g. application of a coating, for example an adhesive coating, and chemical modification of the surface.

The monomers with high reactivity may be a single species or a combination of two or more species. Examples of monomers with high reactivity are monomers having at least two cross-linkable groups per molecule such as monomers containing (meth)acryloyl groups (such as trimethylolpropane tri(meth)acrylate, pentaerythritol (meth)acrylate), ethylene glycol di(meth)acrylate, tetraethylene glycol di(meth)acrylate, polyethylene glycol di(meth)acrylate, 1,4-butanediol di(meth)acrylate, 1,6-hexanediol di(meth)acrylate, neopentyl glycol di(meth)acrylate, polybutanediol di(meth)acrylate, tripropyleneglycol di(meth)acrylate, glycerol tri(meth)acrylate, phosphoric acid mono- and di(meth)acrylates, C₇-C₂₀ alkyl di(meth)acrylates, trimethylolpropanetrioxyethyl (meth)acrylate, tris(2-hydroxyethyl)isocyanurate tri(meth)acrylate, tris(2-hydroxyethyl)isocyanurate di(meth)acrylate, pentaerythritol tri(meth)acrylate, pentaerythritol tetra(meth)acrylate, dipentaerythritol monohydroxy pentacrylate, dipentaerythritol hexacrylate, tricyclodecane diyl dimethyl di(meth)acrylate and alkoxylated versions, preferably ethoxylated and/or propoxylated, of any of the preceding monomers, and also di(meth)acrylate of a diol which is an ethylene oxide or propylene oxide adduct to bisphenol A, di(meth)acrylate of a diol which is an ethylene oxide or propylene oxide adduct to hydrogenated bisphenol A, epoxy (meth)acrylate which is a (meth)acrylate adduct to bisphenol A of diglycidyl ether, diacrylate of polyoxyalkylated bisphenol A, and triethylene glycol divinyl ether, adduct of hydroxyethyl acrylate, isophorone diisocyanate and hydroxyethyl acrylate (HIH), adduct of hydroxyethyl acrylate, toluene diisocyanate and hydroxyethyl acrylate (HTH), and amide ester acrylate.

Examples of monomers with high reactivity having only one crosslinking group per molecule include monomers containing a vinyl group, such as N-vinyl pyrrolidone, N-vinyl caprolactam, vinyl imidazole, vinyl pyridine; isobornyl(meth)acrylate, bornyl(meth)acrylate, tricyclodecanyl (meth)acrylate, dicyclopentanyl (meth)acrylate, dicyclopentenyl (meth)acrylate, cyclohexyl (meth)acrylate, benzyl (meth)acrylate, 4-butylcyclohexyl (meth)acrylate, acryloyl morpholine, (meth)acrylic acid, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, caprolactone acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, tridecyl (meth)acrylate, undecyl (meth)acrylate, lauryl (meth)acrylate, stearyl (meth)acrylate, isostearyl (meth)acrylate, tetrahydrofurfuryl (meth)acrylate, butoxyethyl (meth)acrylate, ethoxydiethylene glycol (meth)acrylate, benzyl (meth)acrylate, phenoxyethyl (meth)acrylate, polyethylene glycol mono(meth)acrylate, polypropylene glycol mono(meth)acrylate, methoxyethylene glycol (meth)acrylate, ethoxyethyl (meth)acrylate, methoxypolyethylene glycol (meth)acrylate, methoxypolypropylene glycol (meth)acrylate, diacetone (meth)acrylamide, beta-carboxyethyl (meth)acrylate, phthalic acid (meth)acrylate, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, butylcarbamylethyl (meth)acrylate, n-isopropyl (meth)acrylamide fluorinated (meth)acrylate, 7-amino-3,7-dimethyloctyl (meth)acrylate, N,N-diethyl (meth)acrylamide, N,N-dimethylaminopropyl (meth)acrylamide, hydroxybutyl vinyl ether, lauryl vinyl ether, cetyl vinyl ether, 2-ethylhexyl vinyl ether; and compounds represented by the following formula (I)

CH₂═C(R⁶)—COO(R⁷O)ₘ—R⁸ (I)

wherein R⁶ is a hydrogen atom or a methyl group; R⁷ is an alkylene group containing 2 to 8, preferably 2 to 5 carbon atoms; and m is an integer from 0 to 12, and preferably from 1 to 8; R⁸ is a hydrogen atom or an alkyl group containing 1 to 12, preferably 1 to 9, carbon atoms; or, R⁸ is a tetrahydrofuran group-comprising alkyl group with 4-20 carbon atoms, optionally substituted with alkyl groups with 1-2 carbon atoms; or R⁸ is a dioxane group-comprising alkyl group with 4-20 carbon atoms, optionally substituted with methyl groups; or R⁸ is an aromatic group, optionally substituted with C₁-C₁₂ alkyl group, preferably a C₈-C₈ alkyl group, and alkoxylated aliphatic monofunctional monomers, such as ethoxylated isodecyl (meth)acrylate, ethoxylated lauryl (meth)acrylate, and the like.

Oligomers with high reactivity include for example aromatic or aliphatic urethane acrylates or oligomers based on phenolic resins (ex. bisphenol epoxy diacrylates), and any of the above oligomers chain extended with ethoxylates. Urethane oligomers may for example be based on a polyol backbone, for example polyether polyols, polyester polyols, polycarbonate polyols, polycaprolactone polyols, acrylic polyols, and the like. These polyols may be used either individually or in combinations of two or more. There are no specific limitations to the manner of polymerization of the structural units in these polyols. Any of random polymerization, block polymerization, or graft polymerization is acceptable. Examples of suitable polyols, polyisocyanates and hydroxyl group-containing (meth)acrylates for the formation of urethane oligomers are disclosed in WO 00/18696.

Preferably, the monomers with high reactivity comprise mono- and/or multifunctional acrylates and mono- and/or multi-functional methacrylates and combinations thereof.

The monomers with low reactivity may be a single species or a combination of two or more species. Examples of monomers with low reactivity or combinations of compounds that together may result in the formation of a crosslinked phase and thus in combination are suitable to be used include for example carboxylic acids and/or carboxylic anhydrides combined with epoxies, acids combined with hydroxy compounds, especially 2-hydroxyalkylamides, amines combined with isocyanates, for example blocked isocyanate, uretdion or carbodiimide, epoxies combined with amines or with dicyandiamides, hydrazinamides combined with isocyanates, hydroxy compounds combined with isocyanates, for example blocked isocyanate, uretdion or carbodiimide, hydroxy compounds combined with anhydrides, hydroxy compounds combined with (etherified) methylolamide (“amino-resins”), thiols combined with isocyanates, thiols combined with acrylates or other vinylic species (optionally radical initiated), acetoacetate combined with acrylates, and when cationic crosslinking is used epoxy compounds with epoxy or hydroxy compounds.

Further possible compounds that may be used as monomers with low reactivity include moisture curable isocyanates, moisture curable mixtures of alkoxy/acyloxy-silanes, alkoxy titanates, alkoxy zirconates, or urea-, urea/melamine-, melamine-formaldehyde or phenol-formaldehyde (resol, novolac types), or radical curable (peroxide- or photo-initiated) ethylenically unsaturated mono- and polyfunctional monomers and polymers, e.g. acrylates, methacrylates, maleate/vinyl ether), or radical curable (peroxide- or photo-initiated) unsaturated e.g. maleic or fumaric, polyesters in styrene and/or in methacrylates.

Also slow reacting compounds with low shrinkage upon polymerization containing one or more oxetane groups can be used similar to epoxy groups. Examples of suitable monomers containing oxetane groups include 3,3-dimethyloxetane, 3-ethyl-3-oxetanemethanol, 3-methyl-3-oxetanemethanol, trimethylene oxide.

Preferably, the monomers with low reactivity are selected from the group consisting of mono- or multifunctional epoxy compounds and combinations thereof.

Examples of non-reactive material include volatile compounds, solvents, and include 1,4-dioxane, acetone, acetonitrile, chloroform, chlorophenol, cyclohexane, cyclohexanone, cyclopentanone, dichloromethane, diethyl acetate, diethyl ketone, dimethyl carbonate, dimethylformamide, dimethylsulphoxide, ethanol, ethyl acetate, m-cresol, mono- and di-alkyl substituted glycols, N,N-dimethylacetamide, p-chlorophenol, 1,2-propanediol, 1-pentanol, 1-propanol, 2-hexanone, 2-methoxyethanol, 2-methyl-2-propanol, 2-octanone, 2-propanol, 3-pentanone, 4-methyl-2-pentanone, hexafluoroisopropanol, methanol, methyl acetate, butyl acetate, methyl acetoacetate, methyl ethyl ketone, methyl propyl ketone, n-methylpyrrolidone-2, n-pentyl acetate, phenol, tetrafluoro-n-propanol, tetrafluoroisopropanol, tetrahydrofuran, toluene, xylene and water. Alcohol, ketone and ester based solvents may also be used, although the solubility of acrylates may become an issue with high molecular weight alcohols. Halogenated solvents (such as dichloromethane and chloroform) and hydrocarbons (such as hexanes and cyclohexanes), are suitable.

Non-volatile compounds, such as, for example, paraffin oils and polyethylene glycols, may also be used as non-reactive material.

As used herein, the term “non-reactive material” refers to materials and compounds that do not to an appreciable extent react with the other components of the polymerizable composition under the normal conditions in the manufacturing method of the present invention.

Photo-sensitive polymerization initiators (photo-initiators) suitable for use in the present invention include any such initiator known to those skilled in the art. This includes for example such photo-sensitive initiators commonly known as free-radical initiators and cationic agents, which upon exposure to actinic light, for example UV- or near-UV-light, generate reactive particles which induces polymerization, i.e. free radicals and cationic compounds, respectively.

The choice of initiator will depend on the different monomers used in the photo-polymerizable composition and will be apparent to those skilled in the art.

For example, the composition may comprise two different photo-initiators.

For example, (meth)acrylate based monomers (with high reactivity) may be polymerized using a first (fast) free-radical initiator, and epoxy-based monomers (with low reactivity) may be polymerized using a second (slow) cationic agent.

When two different photo-initiators are comprised in a photo-polymerizable composition, they may be chosen such that they are activated by the same or different wavelengths.

The polymerizable composition may also comprise other polymerization initiators, such as thermal initiators, for heat-induced polymerization of the reactive monomers.

Thus, combinations of different polymerization initiators may be included in the photo-polymerizable composition of the invention. Examples of this include the combinations of a first photo-sensitive initiator (free-radical initiator or cationic agent) for polymerization of at least monomers with high reactivity and a second photo-sensitive initiator (free-radical initiator or cationic agent) and/or a thermo-sensitive initiator (free-radical initiator or cationic agent) for polymerization of at least the monomers with low reactivity.

Moreover, the polymerizable composition may further comprise additional components, such as surfactants and polymerization inhibitors.

The polymerizable composition may be applied on the substrate in any suitable way, such as spin coating, doctor blade coating, dip-coating, spaying, etc. The composition may form a thin, e.g. 1 to 300 μm, for example 10 to 150 sun, film on the substrate.

The initial, pattern-inducing, exposure may be performed in any way possible for producing the desired light-pattern. For example, it may be performed by radiating the composition by an interference pattern created by holographic techniques. Alternatively, the desired light-pattern may also be obtained with lithographic techniques, i.e. making use of high-resolution light-blocking masks for the exposure, rather than making use of interference patterns.

The pattern may be a periodically repeating pattern having a pitch in the range of from 100 nm to 50 μm, more preferentially 200 nm to 20 μm, which will lead to a corresponding pattern of polymerization of the monomers with high reactivity.

The composition may be exposed to an interference pattern at an essentially perpendicular angle of incidence (˜0°) or at an angle of incidence other than 0°. An angle of incidence different from 0° will lead to a slanted pattern in the composition. In the case of a two-beam system, the above-mentioned angle of incidence is to be understood as the mean value of the angle of incidence for each beam.

The light source may for example be two coherent beams from a laser. Suitable wavelengths of the light source depend on the polymerization-initiating compound, such as the polymerization initiator. The recorded pitch (Λ) may be in the range of 100 nm-50 micron and, in case of a interference pattern, is determined by the wavelength (λ), the angle (θ) between the beams and the refractive index (n) according to the relation:

Λ=λ/(2n sin(θ))

The second exposure, to polymerize the monomers with low reactivity and to form a solid composition, may be performed in any suitable way for effecting polymerization, at least in the parts of the composition not exposed in the initial, pattern inducing, exposure. For example, essentially the complete area of the composition may be exposed. Suitable wavelengths for this second exposure depend on the polymerization-initiating compound. In some cases, the wavelength used for this second exposure may be different from the wavelength used in the first, pattern inducing, exposure, in order to activate a different photo-sensitive polymerization initiator, having a different activation wavelength.

Alternatively, the photo-polymerizable composition comprises a thermal initiator, and the composition is heated to a temperature where polymerization of the monomers with low reactivity is thermally induced.

Also combinations of thermal induction and photo-induction of this polymerization are possible.

After removal of the non-reactive material, the pores in the porous polymerized composition may be filled with optically functional compounds to yield an additional functionality to the solid film. Examples of such functional compounds include, but are not limited to liquid crystals, organic and/or inorganic nano-particles, fluorescent dyes, absorbing dyes, electro-luminescent compounds, conducting materials, semi-conducting materials etc.

For example, liquid crystals may be used to fill the pores in order to obtain a switchable hologram. By applying an electromagnetic field over the hologram, the orientation of the liquid crystals, and thus the optical properties of the hologram, may be affected.

The above-mentioned method and resulting holographic film is not intended to limit the scope of the present invention. It will be apparent for those skilled in the art that variations and modifications to the above are possible without going beyond the scope of the amended claims.

For example, a holographic film of the present invention may constitute a component in an optical device, such as a display device.

The invention is hereafter elucidated by the following non-limiting examples of suitable embodiments.

### EXAMPLES

### Example 1

### According to the Invention

A mixture of 25 wt % dipentaerythitol pentaacrylate, 25 Wt % poly(ethylene glycol)(200)diacrylate, 25 wt % Epicote 157 (an oligomer of glycidyl-ether-bisphenol-A and 25 wt % toluene (with 1% UV-initiator Igracure 184 and 1 wt % UV-sensitive cationic agent) was prepared.

A cell with 18 μm spacers was coated with an adhesion layer of (3-glycidoxypropyl)trimethoxysilane to promote sticking of the film on one substrate after opening the cell and was filled with the mixture and exposed with the 351 nm line of an Ar ion laser (50 mW/cm² each beam) using a 2-beam transmission mode recording geometry with angles at +71.5° and +13.4°.

A subsequent flood exposure of 30 minutes at 70° C. to 365 nm completes the polymerization of the residual acrylates and polymerizes the epoxy (Epicote 157). In this way a slanted transmission grating with period Λ≈450 nm and slant angle φG=23° and refractive index modulation of 0.03 was recorded in films of thickness d=18 μm.

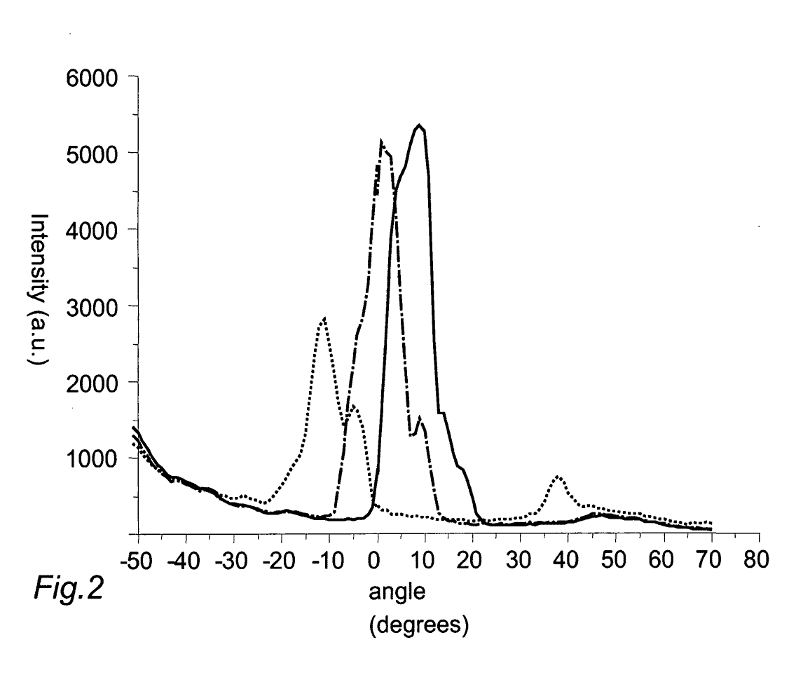

After opening the cell, the solvent is evaporated and the luminance of the outcoupled light from a CCFL was measured using a CCD-spectrometer (Autronic, CCD-spect-2). The angular emission of red (611 nm), green (546 nm), and blue (436 nm) light is obtained at near normal angles (FIG. 2).

### Example 2

### According to the Invention

A mixture of 25 wt % dipentaerythitol pentaacrylate, 25 wt % poly(ethylene glycol)(200)diacrylate, 25 wt % Epicote 157 (an oligomer of glycidyl-ether-bisphenol-A and 25 wt % toluene (with 1% UV-initiator Igracure 184 and 1 wt % UV-sensitive cationic agent) was prepared.

A cell with 5 μm spacers was filled with the mixture and exposed with the 351 nm line of an Ar ion laser (50 mW/cm2 each beam) using a 2-beam transmission mode recording geometry with angles at −22.9 and +22.9 degrees.

A subsequent flood exposure of 30 minutes at 70° C. to 365 nm completes the polymerization of the residual acrylates and polymerizes the epoxy (Epicote 157). In this way a slanted transmission grating with period Λ=450 nm (0° slant angle) was recorded in films of thickness d=5 μm.

After opening the cell, the toluene was evaporated and diffraction efficiencies of 0.975 and 0.726 are obtained at a wavelength of 633 mm at the Bragg angle for P and S polarization respectively. The resulting refractive index modulation is 0.064.

### Example 3

### Not According to the Invention

A mixture of 33 wt % dipentaerythitol pentaacrylate, 33 wt % poly(ethylene glycol)(200)diacrylate, 33 wt % Epicote 157 (an oligomer of glycidyl-ether-bisphenol-A and 0.5 wt % UV-initiator Igracure 184 and 0.5 wt % UV-sensitive cationic agent was prepared. The mixture does not contain any non-reactive material.

A cell with 7 μm spacers was filled with the mixture and exposed with the 351 nm line of an Ar ion laser (50 mW/cm² each beam) using a 2-beam transmission mode recording geometry with angles at −22.9 and +22.9 degrees.

A subsequent uniform exposure of 30 minutes to 365 nm completes the polymerization of the residual acrylates. In this way a slanted transmission grating with period Λ≈450 nm (0° slant angle) was recorded in films of thickness d=7 μm. The resulting refractive index modulation is far below 0.02.

1. A method for the manufacture of a holographic film, comprising:
providing a substrate;
arranging a photo-polymerizable composition on said substrate, said composition comprising:
(i) monomers with high reactivity,
(ii) monomers with low reactivity,
(iii) non-reactive material,
(iv) a photo-sensitive polymerization initiator;
exposing said composition to a light-pattern of bright and dark regions to induce polymerization of at least part of said monomers with high reactivity in parts of said composition exposed to bright regions; and
inducing polymerization of said monomers with low reactivity.

2. A method according to claim 1, further comprising, after polymerization of said monomers with low reactivity, removing at least part of said non-reactive material to form pores in the polymerized composition.

3. A method according to claim 1, wherein said light-pattern is an interference pattern.

4. A method according to claim 1, wherein polymerization of said monomers with low reactivity is induced by exposing said polymerizable composition to light that induces polymerization of said monomers with low reactivity.

5. A method according to claim 1, wherein said polymerizable composition comprises a thermal initiator, said method comprising inducing polymerization of said monomers with low reactivity by heating said polymerizable composition to activate said thermal initiator, thereby inducing polymerization of said monomers with low reactivity.

6. A method according to claim 4, wherein said polymerizable composition comprises a photo-sensitive free-radical initiator for inducing polymerization of at least said monomers with high reactivity and a free-radical initiator and/or a cationic agent for inducing polymerization of at least said monomers with low reactivity.

7. A method according to claim 1, further comprising filling at least part of said pores to comprise a functional compound selected from the group consisting of liquid crystals, organic and/or inorganic nano-particles, fluorescent dyes, absorbing dyes, electro-luminescent compounds, conducting materials, semi-conducting materials and any combinations thereof.

8. A method according to claim 1, wherein said monomers with high reactivity comprise mono- and/or polyfunctional acrylates, mono- and/or polyfunctional methacrylates and any combinations thereof.

9. A method according to claim 1, wherein said monomers with low reactivity comprise mono- and/or polyfunctional epoxy compounds and any combinations thereof.

10. A holographic film obtainable by the method of claim 1.

11. A photo-polymerizable composition comprising monomers with high reactivity, monomers with low reactivity, a photo-initiator and non-reactive material.

12. Use of a photo-polymerizable composition comprising monomers with high reactivity, monomers with low reactivity, a photo-initiator and non-reactive material to form a solid, porous, holographic film.

13. A photo-polymerizable element comprising a photo-polymerizable composition, which comprises monomers with high reactivity, monomers with low reactivity, a photo-initiator and non-reactive material, arranged on a substrate.

14. A holographic film comprising a polymeric film, wherein the refractive index of said polymeric film is periodically spatially modulated between a first and a second refractive index, said first refractive index being higher than said second refractive index,
said polymer film exhibiting a porosity that is periodically spatially modulated between a first and a second porosity, said first porosity being different from said second porosity, and
said polymer film comprises at least a first and a second polymerized monomer, the concentration of said first polymerized monomer being periodically spatially modulated, between a first and a second concentration, said first concentration being higher than said second concentration, wherein said first refractive index, first porosity and first concentration are spatially coincident, and wherein said second refractive index, second porosity and second concentration are spatially coincident.

15. A holographic film according to claim 14, wherein the difference between said first and said second porosity is higher than 1%.

16. A holographic film according to claim 14, having a mean pore size in the range 1-100 nm.

17. A holographic film according to claim 14, wherein the difference between said first refractive index and said second refractive index is higher than 0.02.

18. A holographic film according to claim 17, wherein the difference between said first refractive index and said second refractive index is higher than 0.04.

19. A holographic film according to claim 14, wherein said first polymerized monomer is selected from the group consisting of polymerized mono- and polyfunctional acrylates and methacrylates.

20. A holographic film according to claim 14, wherein said second polymerized monomer is selected from the group consisting of polymerized mono- and polyfunctional epoxy compounds.

21. A holographic film according to claim 14, having pores in the polymer layer at least partially filled with an optically functional compound selected from the group consisting of liquid crystals, fluorescent dyes, absorbing dyes, electro-luminescent compounds, conducting materials, semi-conducting materials and any combination thereof.
